(19) United States
(12) Patent Application Publication
(10) Pub. No.: US 2025/0286347 A1
(43) Pub. Date: Sep. 11, 2025

(54) HIGH-IMPEDANCE SENSING ON III-V SEMICONDUCTOR DEVICE IN AN OPTICAL TRANSCEIVER

(71) Applicant: Marvell Asia Pte Ltd, Singapore (SG)

(72) Inventor: Ricky Yuan Chen, Newbury Park, CA (US)

(21) Appl. No.: 19/073,317

(22) Filed: Mar. 7, 2025

Related U.S. Application Data
(60) Provisional application No. 63/563,303, filed on Mar. 8, 2024.

(51) Int. Cl. H01S 5/068; H01L 25/16; H01S 5/042; H01S 5/062; H04B 10/40

(52) U.S. Cl. CPC H01S 5/06808; H01L 25/167; H01S 5/0421; H01S 5/06203; H04B 10/40

(57) ABSTRACT

A III-V semiconductor device in an optical transceiver includes a signal processing circuit. The signal processing circuit includes processing circuitry configured to receive or transmit an electrical signal corresponding to an optical signal, and feedback control circuitry communicatively coupled to the processing circuitry by a circuit loop. The feedback control circuitry is configured to sense a characteristic of the electrical signal, and based on the sensed characteristic, transmit over the circuit loop a feedback signal to the processing circuitry. The circuit loop includes a first transistor formed using a III-V semiconductor material and configured to function as a first sensing resistor having a first resistance value that limits loading applied to the processing circuitry by the feedback control circuitry.

### CROSS REFERENCE TO RELATED APPLICATION

This disclosure claims the benefit of copending, commonly-assigned U.S. Provisional Patent Application No. 63/563,303, filed Mar. 8, 2024, which is hereby incorporated by reference herein in its entirety.

### FIELD OF USE

This disclosure relates to high-impedance sensing in III-V semiconductor circuitry used in optical devices. More particularly, this disclosure relates to providing high-impedance circuit components in a III-V semiconductor device for optical signaling.

### BACKGROUND

The background description provided herein is for the purpose of generally presenting the context of the disclosure. Work of the inventors hereof, to the extent the work is described in this background section, as well as aspects of the description that may not otherwise qualify as prior art at the time of filing, are neither expressly nor impliedly admitted to be prior art against the subject matter of the present disclosure.

Semiconductor devices such as, for example, those used for optical communications, may include circuitry that requires sensing of signals (e.g., for feedback control). In order to avoid loading on the circuit being sensed, the sensing circuitry should have high impedance. However, for some types of semiconductor materials—e.g., so-called “III-V” semiconductors that incorporate elements from Groups III and V (former nomenclature) of the periodic table, such as gallium arsenide (GaAs) or indium phosphide (InP) —it is difficult to fabricate resistors having high resistance values to provide that high-impedance sensing.

For example, resistors may be formed as thin-film resistors (TFRs) whose sheet resistivity is a certain value per square of the sheet resistor material, regardless of the dimensions of the square. In a III-V semiconductor such as GaAs or InP, the sheet resistivity may be as low as about 50Ω/square, with a typical resistor having dimensions of at least 2 μm by 2 μm. Therefore, to achieve a resistance of about 50 kΩ, as might be required for high-impedance sensing, would require 1,000 resistors, each having a dimension of at least 2 μm by 2 μm, coupled in series. Such a chain of resistors would occupy an area of 2 μm by 2 mm plus the area occupied by the space between resistors and by the conductors that couple them together. An area greater than 2 μm by 2 mm is an extremely large area to devote to such a resistor chain at the scale of integrated circuit components.

One known alternative to such a chain of thin-film resistors is to use a reverse-biased diode, whose current leakage can stand in for, or behave as, a large resistor. However, reverse-biased diodes suffer from excessive temperature variations, process variations between dies and even from site to site on the same die, and mismatch, all of which negatively impact device yield.

### SUMMARY

In accordance with implementations of the subject matter of this disclosure, a III-V semiconductor device in an optical transceiver includes a signal processing circuit. The signal processing circuit includes processing circuitry configured to receive or transmit an electrical signal corresponding to an optical signal, and feedback control circuitry communicatively coupled to the processing circuitry by a circuit loop, the feedback control circuitry being configured to sense a characteristic of the electrical signal, and based on the sensed characteristic, transmit over the circuit loop a feedback signal to the processing circuitry. The circuit loop includes a first transistor formed using a III-V semiconductor material and configured to function as a first sensing resistor having a first resistance value that limits loading applied to the processing circuitry by the feedback control circuitry.

In a first implementation of such a III-V semiconductor device, in an optical transceiver, the first transistor may be a bipolar junction transistor.

According to a first aspect of that first implementation, the bipolar junction transistor may be configured to operate in a linear region, the bipolar junction transistor having an output resistance proportional to early effect voltage of the bipolar junction transistor.

According to a second aspect of that first implementation, the first transistor may be configured to operate in a saturation region for sensing signals having an offset no greater than a range of the saturation region.

In a second implementation of such a III-V semiconductor device, in an optical transceiver, the first transistor may be a field-effect transistor.

In a third implementation of such a III-V semiconductor device, in an optical transceiver, the electrical signal may be a differential signal, the circuit loop may further include a second transistor formed using a III-V semiconductor material and configured to function as a second sensing resistor that limits loading applied to the processing circuitry by the feedback control circuitry, the first transistor may be configured to sense one leg of the differential signal, and the second transistor may be configured to sense another leg of the differential signal.

According to a first aspect of that third implementation, the feedback control circuitry may be an offset cancellation loop.

According to a second aspect of that third implementation, the feedback control circuitry may be further configured to sense a reference voltage, and the feedback control loop may further include a third transistor and a fourth transistor, both the third transistor and the fourth transistor having respective output resistance values that limit loading of the reference voltage.

In a first instance of that second aspect, the feedback control circuitry may be a common mode voltage control loop.

In a fourth implementation of such a III-V semiconductor device, in an optical transceiver, the processing circuitry configured to receive or transmit the electrical signal corresponding to the optical signal may include optical driver circuitry configured to drive a laser diode to output the optical signal.

In a fifth implementation of such a III-V semiconductor device, in an optical transceiver, the processing circuitry configured to receive or transmit the electrical signal corresponding to the optical signal may include optical driver circuitry configured to drive an optical modulator to output the optical signal.

In a sixth implementation of such a III-V semiconductor device, in an optical transceiver, the processing circuitry may include a transimpedance amplifier configured to amplify signals received from at least one photodiode.

In accordance with implementations of the subject matter of this disclosure, a method for configuring a III-V semiconductor device in an optical transceiver includes configuring processing circuitry to receive or transmit an electrical signal corresponding to an optical signal, communicatively coupling feedback control circuitry to the processing circuitry by a circuit loop including forming a first transistor, in the circuit loop, from a III-V semiconductor material to function as a first sensing resistor having a first resistance value that limits loading applied to the processing circuitry by the feedback control circuitry, and configuring the feedback control circuitry to sense a characteristic of the electrical signal, and based on the sensed characteristic, feed back a control signal over the circuit loop to the processing circuitry.

In a first implementation of such a method, forming the first transistor in the circuit loop may include configuring a bipolar junction transistor in the circuit loop.

According to a first aspect of that first implementation, configuring the bipolar junction transistor may include configuring the bipolar junction transistor to operate in a linear region with an output resistance proportional to early effect voltage of the bipolar junction transistor.

According to a second aspect of that first implementation, configuring the bipolar junction transistor may include configuring the bipolar junction transistor operate in a saturation region for sensing signals having an offset no greater than a range of the saturation region.

In a second implementation of such a method, forming the first transistor in the circuit loop may include configuring a field-effect transistor in the circuit loop.

In a third implementation of such a method, configuring the processing circuitry to receive or transmit the electrical signal corresponding to the optical signal may include configuring the processing circuitry for generation of a differential signal, and configuring the feedback control circuitry may further include configuring the first transistor to sense one leg of the differential signal, and configuring a second transistor, formed using a III-V semiconductor material, to function as a second sensing resistor to sense a second leg of the differential signal while limiting loading applied to the processing circuitry by the feedback control circuitry.

In a first instance of that third implementation, configuring the feedback control circuitry may include configuring an offset cancellation loop.

A second instance of that third implementation may further include configuring the feedback control circuitry to sense a reference voltage, including configuring a third transistor and a fourth transistor as sensing resistors in the circuit loop, both the third transistor and the fourth transistor having respective output resistance values that limit loading of the reference voltage.

In a first variation of that second instance, configuring the feedback control circuitry may include configuring a common mode voltage control loop.

In a fourth implementation of such a method, configuring the processing circuitry to receive or transmit the electrical signal corresponding to the optical signal may include configuring optical driver circuitry to drive a laser diode to output the optical signal.

In a fifth implementation of such a method, configuring the processing circuitry to receive or transmit the electrical signal corresponding to the optical signal may include configuring optical driver circuitry to drive an optical modulator to output the optical signal.

In a sixth implementation of such a method, configuring the processing circuitry to receive or transmit the electrical signal corresponding to the optical signal may include configuring a transimpedance amplifier to amplify signals received from at least one photodiode.

In accordance with implementations of the subject matter of this disclosure, a signal processing circuit, formed using a III-V material, includes feedback control circuitry configured to sense a characteristic of a received electrical signal, and based on the sensed characteristic, transmit over a circuit loop a feedback signal. The circuit loop includes a first transistor formed using a III-V semiconductor material and configured to function as a first sensing resistor having a first resistance value that limits loading applied to an output of the feedback control circuitry.

### BRIEF DESCRIPTION OF THE DRAWINGS

Further features of the disclosure, its nature and various advantages, will be apparent upon consideration of the following detailed description, taken in conjunction with the accompanying drawings, in which like reference characters refer to like parts throughout, and in which:

FIG. 1 shows a bipolar junction transistor (which may be implemented in a III-V semiconductor device) configured to act as a large resistor in accordance with implementations of the subject matter of this disclosure;

FIG. 2 is a plot of the collector current (I_{C}) of the bipolar junction transistor of FIG. 1, as a function of the collector-to-emitter voltage (V_{CE}) of the bipolar junction transistor of FIG. 1, showing the early effect voltage in the linear region;

FIG. 3 is a plot of the collector current of the bipolar junction transistor of FIG. 1, as a function of the collector-to-emitter voltage of the bipolar junction transistor of FIG. 1, showing the voltage in the saturation region;

FIG. 4 shows a field-effect transistor, implemented in a III-V semiconductor device, and configured to act as a large resistor in accordance with implementations of the subject matter of this disclosure;

FIG. 5 shows a sensing circuit in which two transistors (which may be implemented in a III-V semiconductor device) are used in accordance with implementations of the subject matter of this disclosure to sense the offset voltage between two signals;

FIG. 6 is a plot of the collector currents of the two transistor of FIG. 5 as a function of their collector-to-emitter voltages, showing determination of the offset voltage in the linear region;

FIG. 7 is a plot of the collector currents of the two transistor of FIG. 5 as a function of their collector-to-emitter voltages, showing determination of the offset voltage in the saturation region;

FIG. 8 shows a single-ended sensing configuration, to sense an output signal for comparison to a reference signal, in accordance with implementations of the subject matter of this disclosure;

FIG. 9 shows a “differential” sensing configuration, to sense a difference between an output signal and a reference signal, in accordance with implementations of the subject matter of this disclosure;

FIG. 10 shows a “differential” sensing configuration similar to FIG. 9 with additional transistors configured as resistors to further decrease current loading on sensed nodes;

FIG. 11 is a block diagram of a receive channel of an optical transceiver which may incorporate transistors configured as sensing resistors in accordance with implementations of the subject matter of this disclosure;

FIG. 12 is a block diagram of a transmit channel of an optical transceiver which may incorporate transistors configured as sensing resistors in accordance with implementations of the subject matter of this disclosure;

FIG. 13 is a block diagram of an alternative implementation of a transmit channel of an optical transceiver which may incorporate transistors configured as sensing resistors in accordance with implementations of the subject matter of this disclosure;

FIG. 14 shows TIA or DRV circuitry in a III-V semiconductor device, configured in accordance with the subject matter of this disclosure for offset cancellation;

FIG. 15 shows TIA or DRV circuitry in a III-V semiconductor device, configured in accordance with the subject matter of this disclosure for common mode control; and

FIG. 16 is a flow diagram illustrating a method according to implementations of the subject matter of this disclosure.

### DETAILED DESCRIPTION

As noted above, semiconductor devices such as, for example, those used for optical communications, may include circuitry that requires sensing of signals (e.g., for feedback control). In order to avoid loading on the circuit being sensed, the sensing circuitry should have high impedance. However, heterojunction transistors and optical components that incorporate laser diodes for transmission and photodiodes for reception are typically formed from types of semiconductor materials—e.g., so-called “III-V” semiconductors that incorporate elements from Groups III and V (former nomenclature) of the periodic table, such as gallium arsenide (GaAs) or indium phosphide (InP) —in which resistors having high resistance values to provide high-impedance sensing are not available.

As further noted above, resistors may be formed as thin-film resistors (TFRs) whose sheet resistivity is a certain value per square of the sheet resistor material, regardless of the dimensions of the square. In a III-V semiconductor such as GaAs or InP, the sheet resistivity may be as low as about 50Ω/square, with a typical resistor having dimensions of at least 2 μm by 2 μm. Therefore, to achieve a resistance of about 50 kΩ, as might be required for high-impedance sensing, would require 1,000 resistors, each having a dimension of at least 2 μm by 2 μm, coupled in series. Such a chain of resistors would occupy an area of 2 μm by 2 mm plus the area occupied by the space between resistors and by the conductors that couple them together. An area greater than 2 μm by 2 mm is an extremely large area to devote to such a resistor chain at the scale of integrated circuit components.

One known alternative to such a chain of thin-film resistors, as discussed above, is to use a reverse-biased diode, whose current leakage can stand in for, or behave as, a large resistor. However, reverse-biased diodes suffer from excessive temperature variations, process variations between dies and even from site to site on the same die, and mismatch, all of which negatively impact device yield.

Therefore, in accordance with implementations of the subject matter of this disclosure, large resistance may be provided in a III-V semiconductor device by using a transistor as a resistor, with large output resistance between the collector and the emitter in a bipolar junction transistor (BJT), or between the source and drain (i.e., the channel resistance) of a field-effect transistor (FET). For a transistor operating a linear region, the output resistance is proportional to the “early effect” voltage V_{A}, which is the voltage at which the linear region of the I-V plot of the transistor output, extended toward the “V” axis, would intersect the “V” axis. For a BJT in a III-V semiconductor device, with collector current I_{C}, where the early effect voltage is much larger than the collector-emitter voltage (V_{A}>>V_{CE}), the output resistance rₒ is proportional to V_{A}/I_{C}. For an FET in a III-V semiconductor device, with drain current I_{D}, the output resistance rₒ=1/(λ×I_{D}).

Alternatively, the transistor in a III-V semiconductor device may be operated in the saturation region where the output resistance is smaller. In saturation in a bipolar junction transistor, r=rₛₐₜ<<rₒ (or in the triode region of a FET, r=r_{ds_on}<<rₒ). Although the resistance is smaller, it is still large enough to allow sensing without applying significant load, and in certain applications, such as error amplification involving a feedback loop, the resulting smaller voltage divider between r_{C} and r_{E} (or between r_{D} and r_{S}) allows the error amplifier gain to be lower, which may be more practical. However, because of the limited voltage range of the saturation region, the voltage than can be sensed may be limited; nevertheless, it may be adequate for some applications.

Various topologies of circuits in a III-V semiconductor device can be implemented for different applications. As described below, there can be single-ended or “differential” topologies (the “differential” topology may measure two different signals rather than the two legs of a true differential signal). Feedback loops can be used for, among other purposes, offset cancellation or common mode offset control, and may be incorporated in transimpedance amplifier circuitry, and/or optical driver circuitry, in optical transceivers.

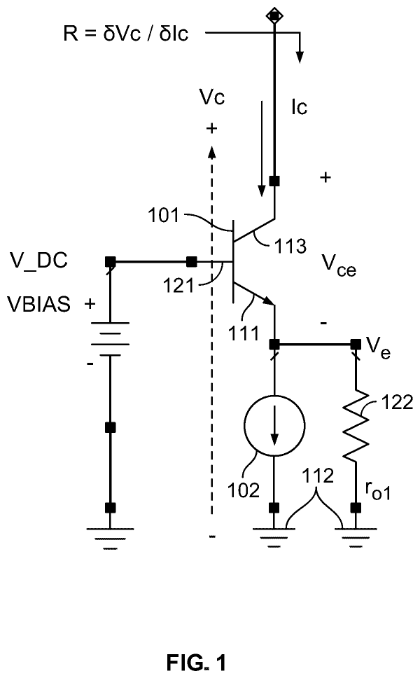

The subject matter of this disclosure may be better understood by reference to FIGS. 1-16.

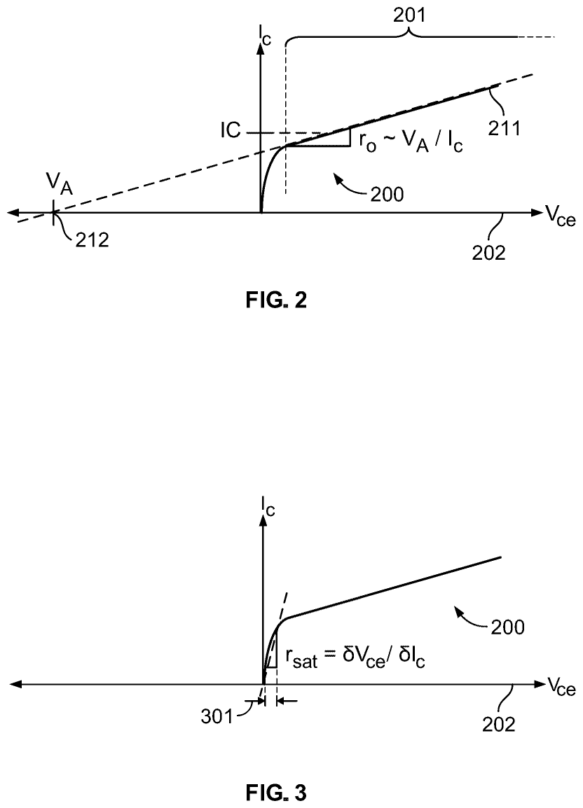

FIG. 1 shows a BJT 101 (which may be implemented in a III-V semiconductor device) configured to act as a large resistor. With a collector current I_{C} provided by current source 102 between emitter 111 and ground 112, and a bias voltage VBIAS applied to base 121, BUT 101 has an output resistance rₒ which can be characterized by a plot of the collector current I_{C} as a function of the collector-to-emitter voltage V_{CE}, as seen in FIGS. 2 and 3. If BJT 101 is operating in the linear region 201, then rₒ, which is the resistance “looking into” collector 113, can be characterized as shown in FIG. 2 by the early effect voltage V_{A}, which can be found by extending the linear portion 211 of I_{C}−V_{CE} plot 200 to intersect with the V_{CE}-axis 202, as seen at intersection point 212, and rₒ can be approximated by V_{A}/I_{C}. If BJT 101 is operating in the saturation region 301, then rₒ may be characterized as shown in FIG. 3 by rₛₐₜ=δV_{C}/δI_{C}. In either linear region 201 or saturation region 301, resistance R, looking into collector 113, may be approximated by gₘ×rₒ×r₁, where gₘ is the transconductance of BJT 101 and r₁ is the inherent resistance 122 of current source 102.

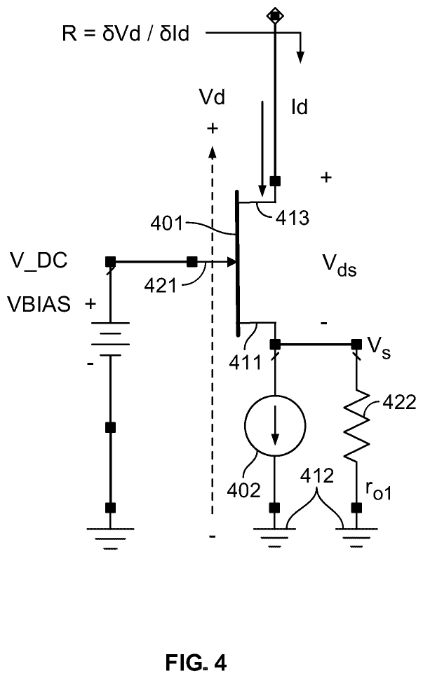

As seen in FIG. 4, a FET 401 (which may be implemented as a metal-semiconductor FET, or MESFET, in a III-V semiconductor device) may be used as a resistor instead of using BJT 101 as a resistor. With a drain current I_{d} provided by current source 402 between source 411 and ground 412, and a bias voltage VBIAS applied to gate 421, FET 401 has an output resistance rₒ which can be characterized by a plot of the drain current I_{d} as a function of the drain-to-source voltage V_{ds}. If FET 401 is operating in the saturation region 201 (comparable to the linear region of a BJT), then rₒ, which is the resistance “looking into” drain 413, can be approximated as rₒ=1/(λ×I_{d}). If FET 401 is operating in the triode region 301 (comparable to the saturation region of a BJT), then rₒ may be characterized by r_{ds_on}. In both saturation region 201 and the triode region 301, resistance R looking into drain 413 may be approximated by gₘ×rₒ×r₁, where gₘ is the transconductance of FET 401 and r₁ is the inherent resistance 422 of current source 402. In the remainder of the description to follow, only BJT implementations will be shown, but each can be implemented with FETs as well.

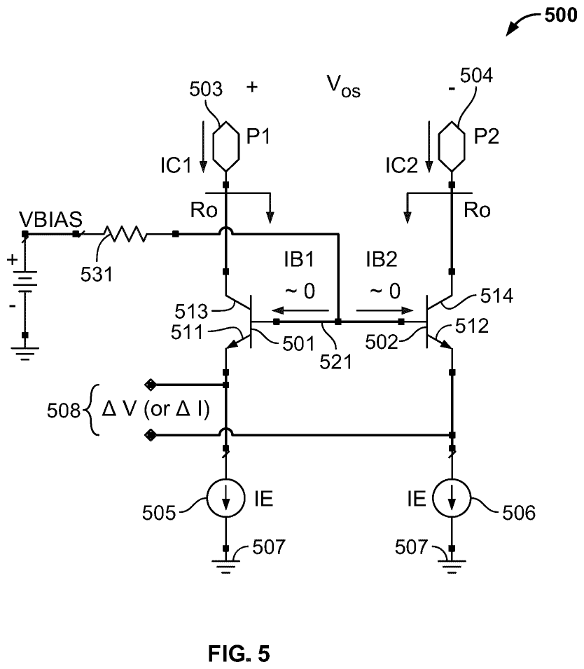

FIG. 5 shows a “differential” sensing circuit 500 in which transistors 501, 502 (which may be implemented in a III-V semiconductor device) are used to sense the offset voltage V_{OS} between two signals on pins P1 (503) and P2 (504). Pins 503, 504 may represent two legs of a true differential signal, or may represent two separate signals whose difference or offset is to be sensed. Transistors 501, 502 are arranged in a common-base configuration, with bias voltage VBIAS applies to base 521 through bias resistor 531. Respective collector currents I_{C1}, I_{C2} are provided by current sources 505, 506 between emitters 511, 512 and ground 507. Current sources 505, 506 may be the same, or, in some implementations, as described below, an offset may be desired. An offset can be created by changing the relative current densities JE (JE=IE/emitter area), either by changing the emitter area ratios, or the current ratios, or both. If the current density ratio is labeled JR, the offset may be proportional to VT×ln(JR), where VT=KT/q.

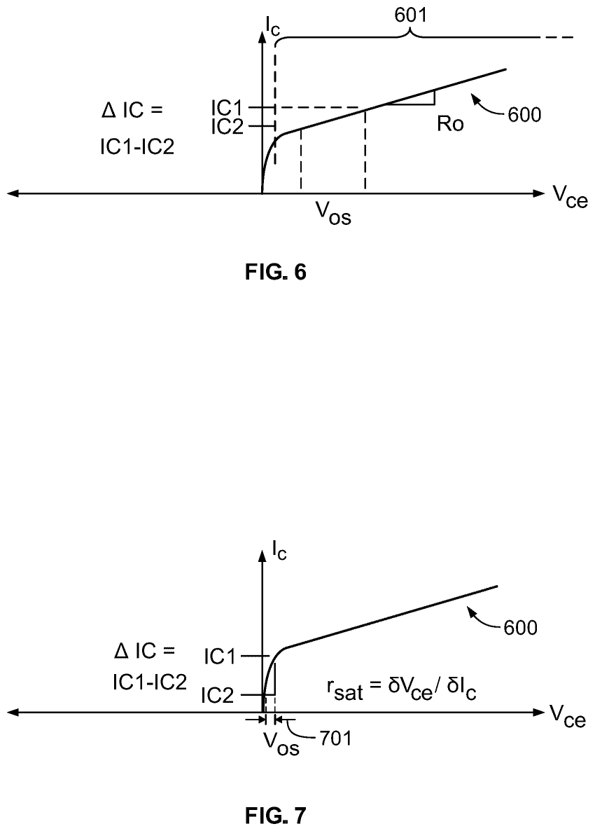

If transistors 501, 502 are operating in the linear region 601 (FIG. 6), then V_{OS} may be sensed via output resistance Rₒ, which is the resistance “looking into” collectors 513, 514. V_{OS} can be read off plot 600 after determining ΔIC=IC1−IC2, and is output as ΔI or ΔV at 508, assuming the base currents IB1, IB2 are approximately the same and approximately 0 (i.e., the gains β of transistors 501, 502 are much greater than 1). As seen in FIG. 7, the same is true if transistors 501, 502 are operating in the saturation region 701, except that the magnitude of the offset voltage V_{OS} that can be sensed using rₛₐₜ is limited by the size of the saturation region.

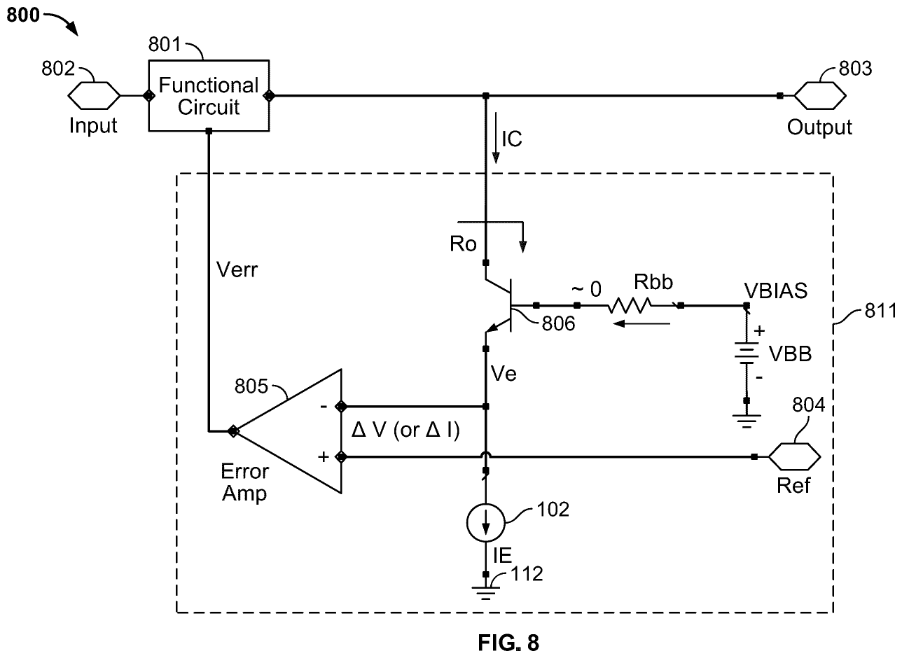

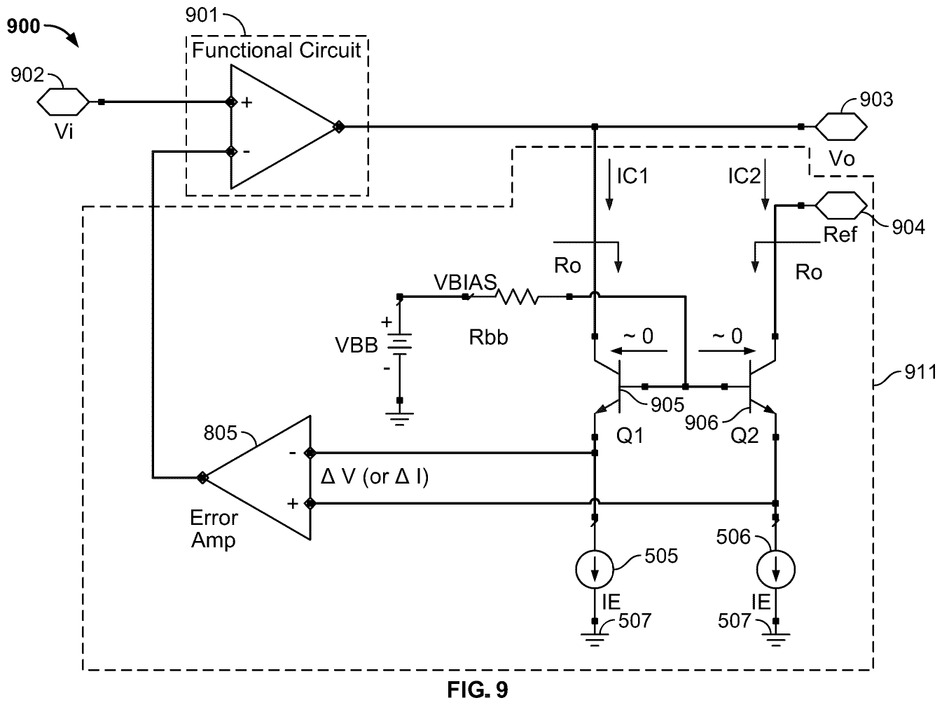

In a generic single-ended sensing configuration 800 shown in FIG. 8, a functional circuit 801, which can be any circuit that performs a function needed by a user, and which includes feedback adjustment 811, has an input at pin 802 and an output at pin 803. Output 803 is compared to a reference input at pin 804 by error amplifier 805 (which may be a transimpedance amplifier, transconductance amplifier, voltage amplifier or current amplifier). Output 803 is sensed (as a current or a voltage) using transistor 806 (in this III-V semiconductor implementation) as a high-value resistor as described above in connection with FIGS. 1-3, so that feedback adjustment 811 can adjust output 803 to match reference 804.

In a generic differential, or matched sense, configuration 900 as shown in FIG. 9, functional circuit 901, including feedback adjustment 911, has an input at pin 902 and an output at pin 903. Output 903 is compared to a reference input at pin 904. In this implementation, for better sense matching over process variations, both output 903 and reference 904 are sensed by transistors 905, 906, each of which provides high-resistance value Ro in this III-V semiconductor implementation as described above in connection with FIGS. 5-7, so that feedback adjustment 911 can adjust output 903 to match reference 904. The sizes of transistors 905, 906, and particularly their emitter areas, can be varied (as described above in connection with FIG. 5) to provide voltage offset between output 903 and reference 904, such as in a proportional-to-absolute-temperature (PTAT) device.

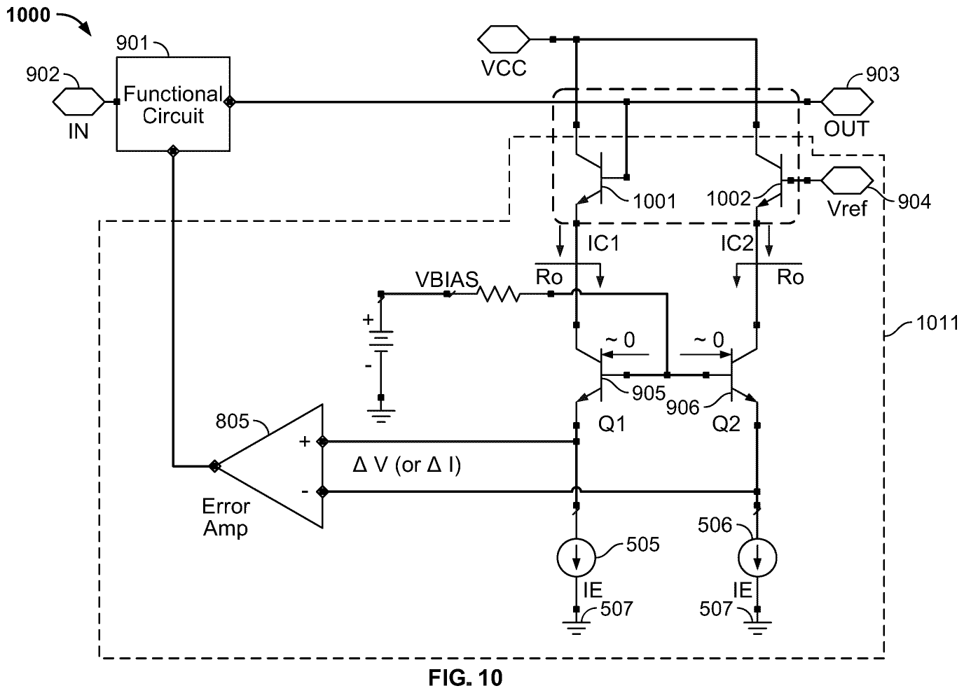

In the arrangement of FIG. 10, including feedback adjustment 1011, transistors 1001, 1002 are added as additional resistors to further decrease the current loading on the sensed nodes. Transistor 1001, in an emitter-follower configuration, lowers the current loading on output node 903. Transistor 1002 similarly lowers the current loading on reference node 904. Moreover, each of transistors 1001, 1002 can be a Darlington pair, further reducing the current loading.

Implementations of the subject matter of this disclosure may have particular application in III-V semiconductor circuitry in an optical transceiver.

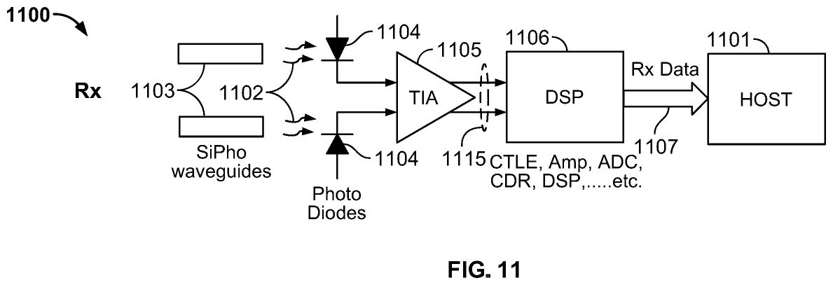

FIG. 11 shows, in block diagram form, the receive channel 1100 of an optical transceiver, coupled to a host device 1101. Optical signals 1102, delivered, for example, via silicon photonics waveguides 1103, are received at photodiodes 1104 and input, as a differential signal (in this implementation), to transimpedance amplifier (TIA) 1105 (as an example of the “functional circuit” described above), which may be implemented, in accordance with implementations of the subject matter of this disclosure, in a III-V semiconductor device. TIA output signal 1115 (also differential in this implementation) is processed in signal processing circuitry 1106, which may include one or more of a continuous time linear equalizer (CTLE), an amplifier, an analog-to-digital converter (ADC), clock-data recovery (CDR) circuitry, and digital signal processing (DSP) circuitry. The processed received data signals 1107 are delivered to host device 1101.

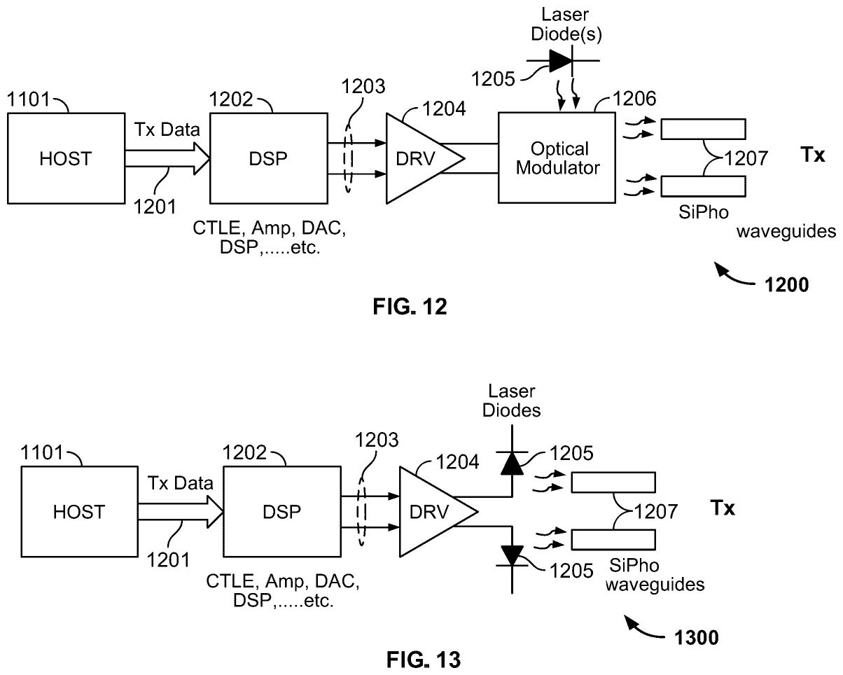

Similarly, FIG. 12 shows, in block diagram form, the transmit channel 1200 of an optical transceiver, coupled to a host device 1101. Data 1201, to be transmitted, is delivered to signal processing circuitry 1202, which may include one or more of a continuous time linear equalizer (CTLE), an amplifier, a digital-to-analog converter (DAC), and digital signal processing (DSP) circuitry. The processed transmit data signals 1203 are input to driver (DRV) 1204 (as another example of the “functional circuit” described above), which may be implemented, in accordance with implementations of the subject matter of this disclosure, in a III-V semiconductor device. Driver 1204 drives an optical modulator 1206, which modulates an optical signal (e.g., a continuous beam or a continuous stream of pulses) generated by one or more laser diodes 1205, for transmission onto silicon photonics waveguides 1207.

An alternative Direct Modulation Laser (DML) implementation of a transmit channel 1300 of an optical transceiver, coupled to a host device 1101, is shown in FIG. 13. Data 1201, to be transmitted, is delivered to signal processing circuitry 1202, which may include one or more of a continuous time linear equalizer (CTLE), an amplifier, a digital-to-analog converter (DAC), and digital signal processing (DSP) circuitry. The processed transmit data signals 1203 are input to driver (DRV) 1204, which may be implemented, in accordance with implementations of the subject matter of this disclosure, in a III-V semiconductor device. Driver 1204 drives laser diodes 1305 to convert data signals 1203 to optical signals 1315, which are transmitted directly onto silicon photonics waveguides 1207.

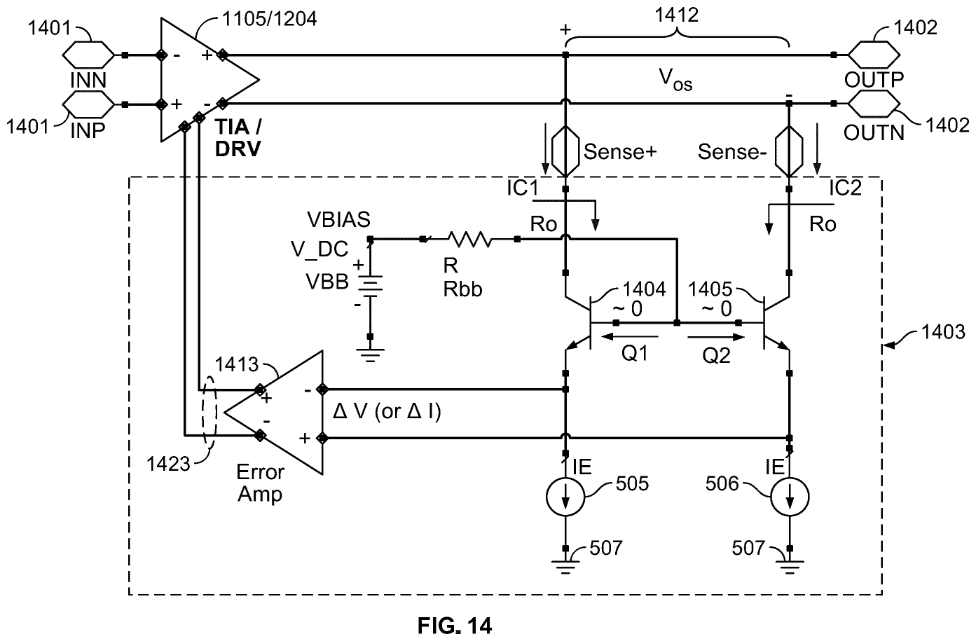

As seen in FIG. 14, one implementation 1400 in which a TIA 1105 or DRV 1204 (in a III-V semiconductor device), in accordance with the subject matter of this disclosure, is configured for offset cancellation. Signals 1401 may be input to the TIA or DRV from photodiodes 1104 or signal processing circuitry 1202. Any offset voltage V_{OS} (1312) in output signals 1402 may be sensed by loop 1403 in which offset voltage V_{OS} (1412) is converted to ΔV or ΔI, for input to error amplifier 1413, which generates an error signal 1423, which can be used in the TIA or DRV to reduce or eliminate the offset voltage V_{OS} (1412). In accordance with implementations of the subject matter of this disclosure, the sensing of offset voltage V_{OS} (1412) in loop 1403 may be performed using the output resistance Ro of transistors 1404, 1405 in place of high resistance to reduce loading of output signals 1402. As described above in connection with FIG. 9, the sizes of transistors 1404, 1405, and particularly their emitter areas, can be varied to provide an intentional offset, such as in a PTAT device.

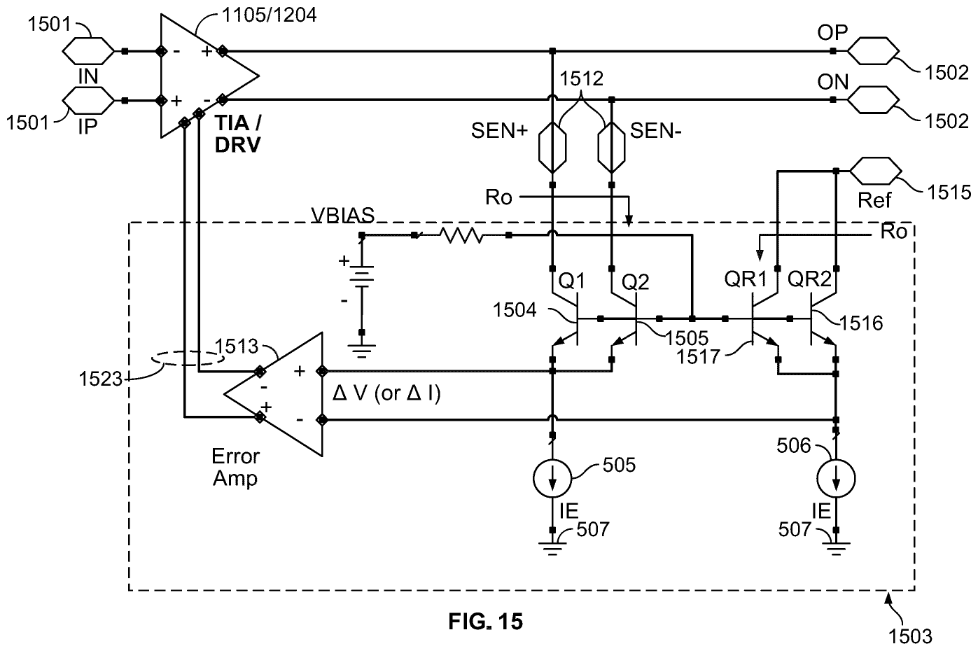

FIG. 15 shows an implementation 1500 in which a TIA 1105 or DRV 1204 (in a III-V semiconductor device), in accordance with the subject matter of this disclosure, having differential input signals 1501, is configured for common mode control, in which differential output signals 1502 are sensed at 1512 and compared by error amplifier 1513 to reference voltage 15, providing a control signal 1523 that causes the common mode voltage of signals 1502 to track reference voltage 1515. In accordance with implementations of the subject matter of this disclosure, the sensing of differential output signals 1502 in loop 1503 may be performed using the output resistance Ro of transistors 1504, 1505 in place of high resistance to reduce loading of output signals 1502. As described above in connection with FIG. 9, reference voltage 1515 also may be sensed using high impedance (e.g., the output resistance Ro of transistors 1516, 1517) for better sense matching over process variations.

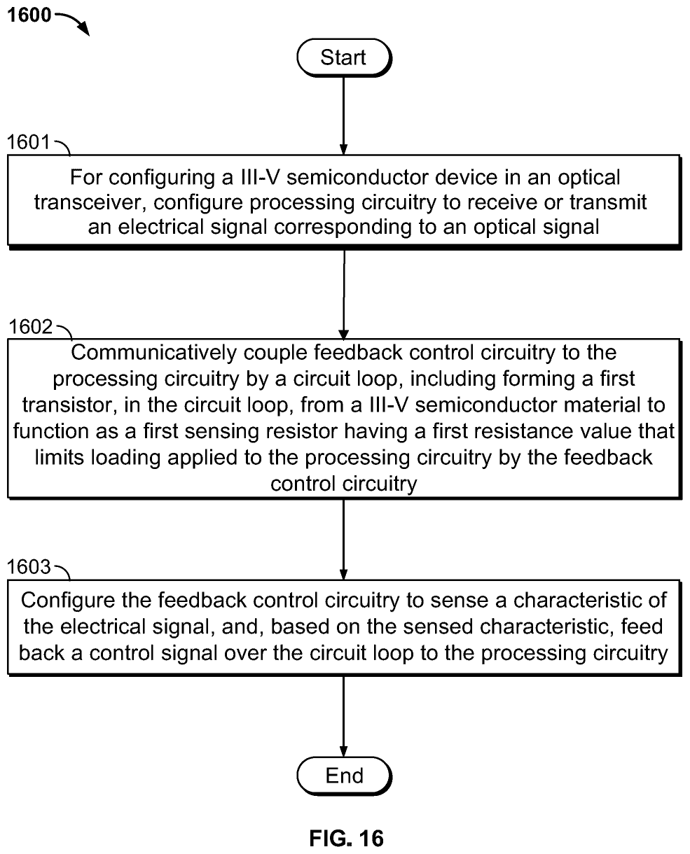

More generally, a method 1600 according to implementations of the subject matter of this disclosure, for configuring signal processing circuitry of an optical transceiver in a III-V semiconductor device, is diagrammed in FIG. 16. At 1601, for configuring a III-V semiconductor device in an optical transceiver, processing circuitry is configured to receive or transmit an electrical signal corresponding to an optical signal. At 1602, feedback control circuitry is communicatively coupled to the processing circuitry by a circuit loop, including forming a first transistor, in the circuit loop, from a III-V semiconductor material to function as a first sensing resistor having a first resistance value that limits loading applied to the processing circuitry by the feedback control circuitry. At 1603, the feedback control circuitry is configured to sense a characteristic of the electrical signal, and, based on the sensed characteristic, feed back a control signal over the circuit loop to the processing circuitry. Method 1600 then ends.

Thus it is seen that a method for providing high-impedance components in a III-V semiconductor device for optical signaling, and apparatus including high-impedance components in a III-V semiconductor device for optical signaling, have been provided.

As used herein and in the claims which follow, the construction “one of A and B” shall mean “A or B.”

It is noted that the foregoing is only illustrative of the principles of the invention, and that the invention can be practiced by other than the described embodiments, which are presented for purposes of illustration and not of limitation, and the present invention is limited only by the claims which follow.

What is claimed is:

1. A III-V semiconductor device in an optical transceiver, including a signal processing circuit, the signal processing circuit comprising:
processing circuitry configured to receive or transmit an electrical signal corresponding to an optical signal; and
feedback control circuitry communicatively coupled to the processing circuitry by a circuit loop, the feedback control circuitry being configured to:
sense a characteristic of the electrical signal, and
based on the sensed characteristic, transmit over the circuit loop a feedback signal to the processing circuitry; wherein:
the circuit loop comprises a first transistor formed using a III-V semiconductor material and configured to function as a first sensing resistor having a first resistance value that limits loading applied to the processing circuitry by the feedback control circuitry.

2. The III-V semiconductor device, in an optical transceiver, according to claim 1, wherein the first transistor is a bipolar junction transistor.

3. The III-V semiconductor device, in an optical transceiver, according to claim 2, wherein the bipolar junction transistor is configured to operate in a linear region, the bipolar junction transistor having an output resistance proportional to early effect voltage of the bipolar junction transistor.

4. The III-V semiconductor device, in an optical transceiver, according to claim 2, wherein the first transistor is configured to operate in a saturation region for sensing signals having an offset no greater than a range of the saturation region.

5. The III-V semiconductor device, in an optical transceiver, according to claim 1, wherein the first transistor is a field-effect transistor.

6. The III-V semiconductor device, in an optical transceiver, according to claim 1, wherein:
the electrical signal is a differential signal;
the circuit loop further comprises a second transistor formed using a III-V semiconductor material and configured to function as a second sensing resistor that limits loading applied to the processing circuitry by the feedback control circuitry; and
the first transistor is configured to sense one leg of the differential signal, and the second transistor is configured to sense another leg of the differential signal.

7. The III-V semiconductor device, in an optical transceiver, according to claim 6, wherein the feedback control circuitry is an offset cancellation loop.

8. The III-V semiconductor device, in an optical transceiver, according to claim 6, wherein:
the feedback control circuitry is further configured to sense a reference voltage; and
the feedback control loop further comprises a third transistor and a fourth transistor, both the third transistor and the fourth transistor having respective output resistance values that limit loading of the reference voltage.

9. The III-V semiconductor device, in an optical transceiver, according to claim 8, wherein the feedback control circuitry is a common mode voltage control loop.

10. The III-V semiconductor device, in an optical transceiver, according to claim 1, wherein the processing circuitry configured to receive or transmit the electrical signal corresponding to the optical signal comprises optical driver circuitry configured to drive a laser diode to output the optical signal.

11. The III-V semiconductor device, in an optical transceiver, according to claim 1, wherein the processing circuitry configured to receive or transmit the electrical signal corresponding to the optical signal comprises optical driver circuitry configured to drive an optical modulator to output the optical signal.

12. The III-V semiconductor device, in an optical transceiver, according to claim 1, wherein the processing circuitry comprises a transimpedance amplifier configured to amplify signals received from at least one photodiode.

13. A method for configuring a III-V semiconductor device in an optical transceiver, the method comprising:
configuring processing circuitry to receive or transmit an electrical signal corresponding to an optical signal;
communicatively coupling feedback control circuitry to the processing circuitry by a circuit loop including forming a first transistor, in the circuit loop, from a III-V semiconductor material to function as a first sensing resistor having a first resistance value that limits loading applied to the processing circuitry by the feedback control circuitry; and
configuring the feedback control circuitry to:
sense a characteristic of the electrical signal, and
based on the sensed characteristic, feed back a control signal over the circuit loop to the processing circuitry.

14. The method according to claim 13, wherein forming the first transistor in the circuit loop comprises configuring a bipolar junction transistor in the circuit loop.

15. The method according to claim 14, wherein configuring the bipolar junction transistor comprises configuring the bipolar junction transistor to operate in a linear region with an output resistance proportional to early effect voltage of the bipolar junction transistor.

16. The method according to claim 14, wherein configuring the bipolar junction transistor comprises configuring the bipolar junction transistor operate in a saturation region for sensing signals having an offset no greater than a range of the saturation region.

17. The method according to claim 13, wherein forming the first transistor in the circuit loop comprises configuring a field-effect transistor in the circuit loop.

18. The method according to claim 13, wherein:
configuring the processing circuitry to receive or transmit the electrical signal corresponding to the optical signal comprises configuring the processing circuitry for generation of a differential signal; and
configuring the feedback control circuitry further includes:
configuring the first transistor to sense one leg of the differential signal, and
configuring a second transistor, formed using a III-V semiconductor material, to function as a second sensing resistor to sense a second leg of the differential signal while limiting loading applied to the processing circuitry by the feedback control circuitry.

19. The method according to claim 18, wherein configuring the feedback control circuitry comprises configuring an offset cancellation loop.

20. The method according to claim 18, further comprising:
configuring the feedback control circuitry to sense a reference voltage, including configuring a third transistor and a fourth transistor as sensing resistors in the circuit loop, both the third transistor and the fourth transistor having respective output resistance values that limit loading of the reference voltage.

21. The method according to claim 20, wherein configuring the feedback control circuitry comprises configuring a common mode voltage control loop.

22. The method according to claim 13, wherein configuring the processing circuitry to receive or transmit the electrical signal corresponding to the optical signal comprises configuring optical driver circuitry to drive a laser diode to output the optical signal.

23. The method according to claim 13, wherein configuring the processing circuitry to receive or transmit the electrical signal corresponding to the optical signal comprises configuring optical driver circuitry to drive an optical modulator to output the optical signal.

24. The method according to claim 13, wherein configuring the processing circuitry to receive or transmit the electrical signal corresponding to the optical signal comprises configuring a transimpedance amplifier to amplify signals received from at least one photodiode.

25. A signal processing circuit formed using a III-V material, the signal processing circuit comprising:
feedback control circuitry configured to:
sense a characteristic of a received electrical signal, and
based on the sensed characteristic, transmit over a circuit loop a feedback signal; wherein:
the circuit loop comprises a first transistor formed using a III-V semiconductor material and configured to function as a first sensing resistor having a first resistance value that limits loading applied to an output of the feedback control circuitry.
